(19) United States
(12) Patent Application Publication
(10) Pub. No.: US 2010/0295045 A1
(43) Pub. Date: Nov. 25, 2010

(54) Tape carrier package, individual tape carrier package product, and method of manufacturing the same

(75) Inventor: Isao Yoshino, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: Renesas Electronics Corporation, Kawasaki (JP)

(21) Appl. No.: 12/801,061

(22) Filed: May 19, 2010

(30) Foreign Application Priority Data
May 22, 2009 (JP) 2009-124539

(51) Int. Cl. H01L 23/544; H01L 21/78; H01L 23/498

(52) U.S. Cl. 257/48; 438/462; 257/620; 257/734; 257/E23.179; 257/E23.065; 257/E21.599

(57) ABSTRACT

A tape carrier package includes: a tape base; and interconnections formed on the tape base and extending to intersect a cutting line. At least a slit is formed along each of the interconnections, to intersect the cutting line and to divide the interconnection into a plurality of interconnection elements.

### INCORPORATION BY REFERENCE

This patent application claims a priority on convention based on Japanese Patent Application No. 2009-124539 filed on May 22, 2009. The disclosure thereof is incorporated herein by reference.

### TECHNICAL FIELD

The present invention relates to a tape carrier package, an individual tape carrier package product, and a method of manufacturing the same.

### BACKGROUND ART

There is known a TCP (Tape Carrier Package). It is assumed that types of TCPs include a so-called COF (Chip On Film) package. The TCP has a structure in which a semiconductor chip is mounted on an insulating tape base. Because of use of the tape base, the TCP can be made thin and used in various purposes such as a LCD driver device.

In the TCP, a plurality of semiconductor chips are mounted on one tape base. Thereinafter, the tape base is cut off along a predetermined cutting line, thereby obtaining a plurality of individual products. In the specification of the present application, the TCP before cutting is referred to simply as “TCP” and the individual products after cutting are referred to “individual TCP products”.

An interconnection group connected to a plurality of semiconductor chips is formed on the tape base. This interconnection group often extends to cross the cutting line. For example, test terminals are often provided on the tape base to test electric characteristics of the semiconductor chips. In this case, the interconnection group extends to connect the test terminals to the semiconductor chips. The test terminals are unnecessary for the individual TCP products. Therefore, the cutting line is set to divide the tape base into a region where the test terminals are provided and a region where the semiconductor chips are mounted. In this case, the cutting line intersects the interconnection group.

If the interconnection group intersects the cutting line, a defect often occurs during cutting. For example, if one interconnection deforms during the cutting, a short-circuited path is generated among the deformed interconnection and other interconnections. Further, if one interconnection is broken during cutting, broken pieces of the interconnection often produces a short-circuited path among adjacent interconnections.

Patent literature 1 describes a technique for solving a defect in the cutting. In the patent literature 1, the width of a cutting portion of a conductor pattern in a user area or a conductor pattern connected to a test terminal is made narrower than the width of a conductor pattern in a portion serving as at least a connection lead and pressing is performed along narrower cut portions. According to the Patent literature 1, a deformation amount is reduced in the cutting because of a narrow conductor pattern. Further, a scattering quantity of broken pieces is considerably reduced. This can overcome the defect during cutting.

### CITATION LIST

Patent literature 1: JP-A-Heisei 8-254708

### SUMMARY OF THE INVENTION

However, if the narrow portion is provided, the following problems occur. The narrow portion is broken before a test step in a package state of using a test pad, and the test cannot be conducted appropriately.

In an aspect of the present invention, a tape carrier package includes: a tape base; and interconnections formed on the tape base and extending to intersect a cutting line. At least a slit is formed along each of the interconnections, to intersect the cutting line and to divide the interconnection into a plurality of interconnection elements.

In another aspect of the present invention, a tape carrier package individual product includes: a tape base; a semiconductor chip mounted on the tape base; and interconnections formed on the tape base and extending to intersect a cutting line. Each of the interconnections is divided into a plurality of interconnection elements at an end of the tape base.

In still another aspect of the present invention, a manufacturing method of a tape carrier package, is achieved by providing a tape base; by forming interconnections on the tape base to intersect a cutting line; and by forming at least a slit in each of the interconnections. At least a slit is formed along each of the interconnections, to intersect the cutting line and to divide the interconnection into a plurality of interconnection elements.

In yet still another aspect of the present invention, a manufacturing method of a tape carrier package, is achieved by providing a tape base; by forming interconnections on the tape base to intersect a cutting line; by forming at least a slit in each of the interconnections; and by cutting the tape base in which the interconnections have been formed and the slit has been formed, along the cutting line. At least a slit is formed along each of the interconnections, to intersect the cutting line and to divide the interconnection into a plurality of interconnection elements.

According to the present invention, it is possible to prevent the interconnection of the portion intersecting the cutting line from being broken and prevent a test from being conducted inappropriately. The present invention provides a tape carrier package, an individual tape carrier package product, and a method of manufacturing the same.

### BRIEF DESCRIPTION OF THE DRAWINGS

The above and other objects, advantages and features of the present invention will be more apparent from the following description of certain embodiments taken in conjunction with the accompanying drawings, in which:

FIG. 1 is a plan view showing a tape carrier package according to a first embodiment of the present invention;

FIG. 2A is a side view showing a cutting state of the tape carrier package in the first embodiment;

FIG. 2B is an enlarged view of intersecting portion in which interconnections intersect a cutting line in the first embodiment;

FIG. 3 is an enlarged view of the intersecting portions in which interconnections intersect the cutting line in the first embodiment;

FIG. 4 is a partial enlarged view of the tape carrier package according to a second embodiment of the present invention;

FIG. 5 is a partial enlarged view of the tape carrier package according to a third embodiment of the present invention; and

FIG. 6 is a partial enlarged view of the tape carrier package according to a fourth embodiment of the present invention.

### DESCRIPTION OF EMBODIMENTS

Hereinafter, a tape carrier package according to the present invention will be described with reference to the attached drawings.

### First Embodiment

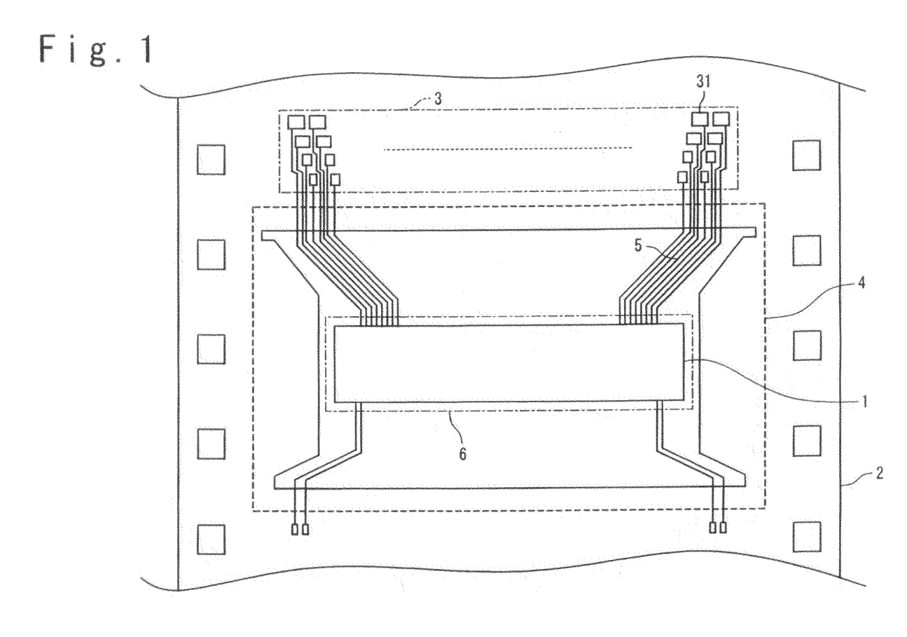

FIG. 1 is a plan view of the tape carrier package according to the first embodiment of the present invention.

The tape carrier package according to the first embodiment includes a tape base 2, a semiconductor chip 1, an interconnection group, and a test region 3. Although a plurality of the semiconductor chips 1 are actually mounted on the tape base 2, FIG. 1 shows only one semiconductor chip 1.

The tape base 2 is made of an insulating resin material or the like. Specifically, polyimide is exemplified as the material of the tape base 2. A chip mount region 6 on which the semiconductor chips 1 are mounted and the test region 3 are provided on the tape base 2. A plurality of test terminals 31 are formed in the test region 3 on the test base 2. The plurality of test terminals 31 are provided to test electric characteristics of the semiconductor chips 1. The interconnection group is formed on the tape base 2. The interconnection group includes a plurality of interconnections 5. The plurality of interconnections 5 extend to electrically connect the semiconductor chip 1 to the plurality of test terminals 31.

After the electric characteristics of the semiconductor chip 1 are tested, this tape carrier package is cut off along cutting line 4. As a result, a plurality of individual tape carrier package products are obtained from one tape carrier package. The test region 3 is unnecessary for the individual tape carrier package products. Accordingly, the cutting line 4 is set to separate the test region 3 from the chip mount region 6. As a result, the plurality of interconnections 5 extend to intersect the cutting line 5.

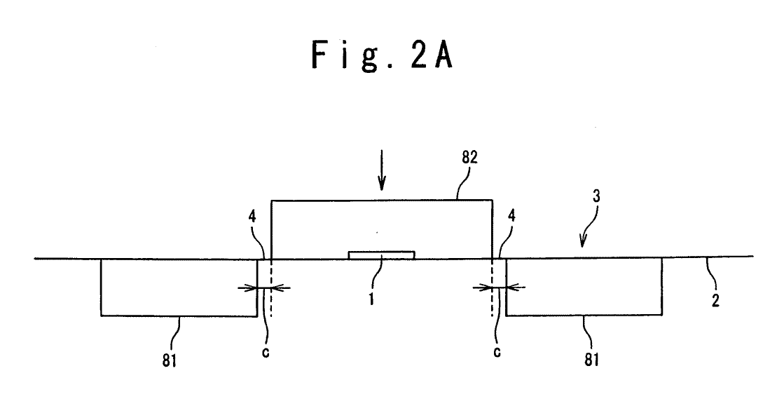

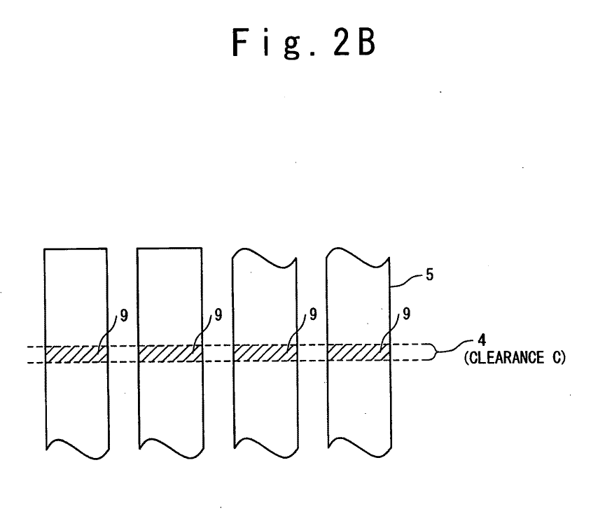

FIG. 2A is a side view showing a state of the tape carrier package in the cutting. As shown in FIG. 2A, in the cutting, the tape base 2 is punched out by using a metal mold having a lower mold 81 and an upper mold 82. In an example shown in FIG. 2A, the tape base 2 is arranged on an upper surface of the lower mold 81. On the upper surface of the lower mold 81, an opening having an edge shaped to correspond to the cutting line 4 is formed. The upper mold 82 is shaped to correspond to the cutting line 4. By pressing the tape base 2 using the upper mold 82, the tape base 2 is punched out. In this case, if a shape of the edge of the opening of the lower mold 81 completely coincides with that of the upper mold 82, the upper mold 82 contacts with the lower mold 81 in the punching. If the upper and lower molds 81 and 82 contact with each other, the tape base 2 is insufficiently punched out. In addition, if the upper and lower molds 81 and 82 contact with each other, mold deformation or the like occurs, resulting in a reduced life of the metal mold. For the reason, clearances C are provided between the upper mold 82 and the lower mold 81.

FIG. 2B is an enlarged view of intersecting portions where the interconnections 5 intersect the cutting line 4. Speaking strictly, the cutting line 4 has a width because of the clearances C as stated above. As a result, broken pieces are generated from portions (broken piece generating regions 9) of the interconnections 5 for the clearances C. If these broken pieces adhere between the interconnections 5, a defect due to a short-circuited path occurs.

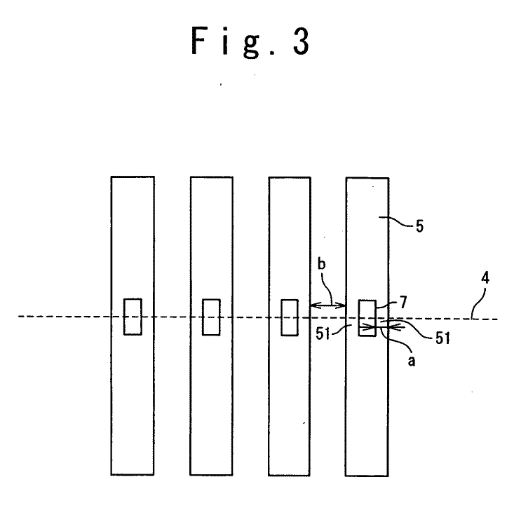

Therefore, in the present embodiment, a slit 7 is formed in each interconnection 5. FIG. 3 is an enlarged view of the intersecting portions, where the interconnections 5 intersect the cutting line 4 of the tape carrier package according to the present embodiment. As shown in FIG. 3, the slits 7 are rectangular openings. The slit 7 extends to intersect the cutting line 4. Each of these slits 7 divides the corresponding interconnection 5 in the intersecting portion where the interconnection 5 intersect the cutting line 4 into a plurality of (two in FIG. 3) interconnection elements 51.

The width “a” of each of a plurality of interconnection elements 51 is smaller than the width of the entire interconnection 5. Therefore, the broken pieces generated in the cutting can be made small in size so as to prevent generation of a short-circuited path due to the broken pieces. In addition, because each interconnection 5 is divided into the plurality of interconnection elements 51, the other interconnection element 51 can keep electrical connection to the semiconductor chip 1, even if one of the interconnection elements 51 is broken before cutting. That is, by providing the slit 7, it is possible to prevent the generation of a short-circuit due to the broken pieces in the cutting while suppressing breaking before cutting.

The width “a” of each interconnection element 51 is preferably smaller than a space “b” between the two adjacent interconnections 5. By setting the width “a” smaller than the space “b”, no short-circuited path is generated between the adjacent interconnection 5 in the space “b” even if the broken pieces are generated in the cutting. This can further ensure preventing of the generation of a short-circuited path in the cutting.

A method of manufacturing the tape carrier package and the individual tape carrier package products according to the present embodiment will next be described.

First, the tape base 2 is prepared. Next, a conductor layer for forming the interconnections 5 is formed on the tape base 2. This conductor layer is patterned by such a method as a lithographic method, thereby forming the interconnections 5. At this time, the conductor layer is patterned so as to form the slits 7. The semiconductor chips 1 are then mounted on the tape base 2. As a result, the tape carrier package is obtained. Thereafter, the tape base 2 is cut off along the cutting line 4. At this time, a probability of breaking the interconnections 5 before a test is reduced and the generation of a short-circuited path among the adjacent interconnections in the space “b” in the cutting is prevented, as already stated. After the cutting, the individual tape carrier package products are obtained. In each of the individual tape carrier package products, each interconnection 5 is shaped to branch into the plurality of interconnection elements 51 on an end.

Furthermore, a user recognizes a position of the tape base 2 by using a camera or the like for positioning at the time of mounting the semiconductor chip 1 or cutting off the tape base 2. The slits 7 can be also used as positioning marks for the positioning.

### Second Embodiment

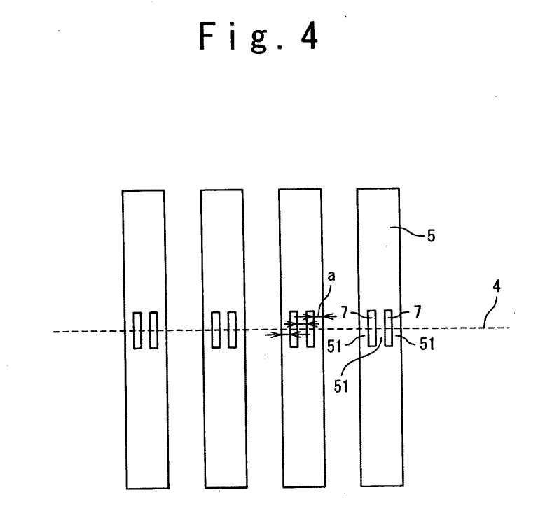

A second embodiment of the present invention will next be described. FIG. 4 is a partial enlarged view of the tape carrier package according to the second embodiment. The second embodiment differs from the first embodiment in the number of slits 7. Since the tape carrier package according to the second embodiment is similar to that according to the first embodiment in the other respects, the similar respects will not be described herein in detail.

As shown in FIG. 4, in the present embodiment, a plurality of (two in FIG. 4) slits 7 are formed in the intersecting portion where one interconnection 5 intersects a cutting line 4.

The second embodiment can provide similar functions and effects to those of the first embodiment. In addition, by providing a plurality of slits 7, the number of interconnection elements 51 can increase. This can further reduce a probability of breaking the interconnections 5 before a test.

### Third Embodiment

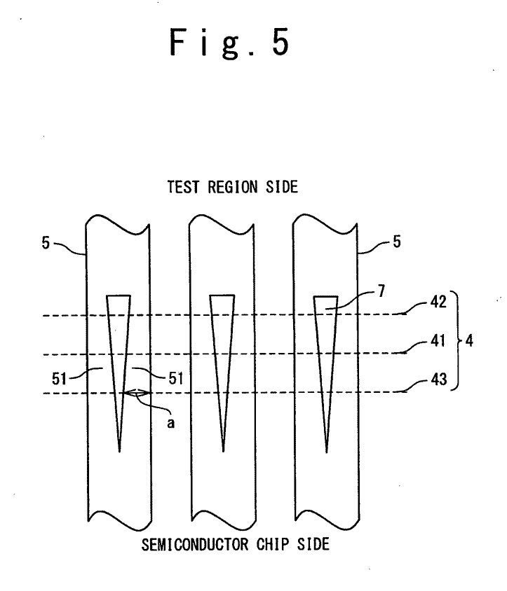

A third embodiment of the present invention will be described. FIG. 5 is a partial enlarged view of the tape carrier package according to the third embodiment. The third embodiment differs from the preceding embodiments in a shape of the slit 7. Since the tape carrier package according to the third embodiment is similar to those according to the first and second embodiments in the other respects, the similar respects will not be described herein in detail.

FIG. 5 shows, as a cutting line 4, a center 41 of the cutting line 4, one end 42 of the cutting line 4, and the other end 43 of the cutting line 4. One end 42 of the cutting line 4 is a test region-side end of the cutting line 4 whereas the other end 43 of the cutting line 4 is a semiconductor chip-side end of the cutting line 4.

As shown in FIG. 5, each slit 7 is provided to be narrower as being closer to the semiconductor chip-side. By providing each slit 7 in such a manner, each interconnection element 51 is thicker as being closer to the semiconductor chip-side. Therefore, if each interconnection 5 is divided into the plurality of interconnection elements 51 by the slit 7, each interconnection element 51 is made narrower. This can prevent the generation of a short-circuited path due to broken pieces in the cutting. However, strength of each interconnection 5 itself weakens by narrowing the interconnection 5. In addition, a bonding area by which the tape base 2 is bonded to each interconnection 5 is made small. As a result, the interconnections 5 tend to separate from the tape base 2 from portions divided by the interconnection elements 51. The interconnections 5 are often used for electrical connection of the individual tape carrier package product to an external component after the cutting. Separation of the interconnections 5 from the tape base 2 reduces reliability of electrical connection between the external component and the individual tape carrier package product.

According to the third embodiment, each interconnection element 51 is thicker as being closer to the semiconductor chip-side. In this way, a bonding force of bonding each interconnection element 51 to the tape base 2 on the semiconductor chip-side is ensured for each interconnection element 51. Even if one interconnection 5 separate from the tape base 2 on an end of each interconnection element 51, progress of separation is suppressed. This can prevent the entire interconnections 5 from separating from the tape base 2 and ensure the reliability of the electrical connection between the external component and the individual tape carrier package product.

In the present embodiment, the width “a” of each interconnection element 51 on the other end 43 of the cutting line 4 is set to be smaller than the space “b”. As the result of such a width, it is possible to ensure preventing the generation of a short-circuited path due to broken pieces in the cutting.

### Fourth Embodiment

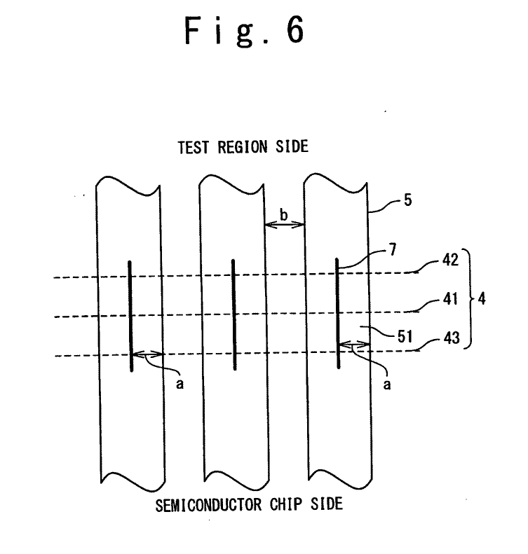

A fourth embodiment of the present invention will be described. FIG. 6 is a partial enlarged view of a tape carrier package according to the fourth embodiment. The fourth embodiment differs from the preceding embodiments in the shape of the slit 7. Since the tape carrier package according to the fourth embodiment is similar to those according to the first to third embodiments in the other respects, the description of the fourth embodiment other than the slits 7 is omitted.

As shown in FIG. 6, in the present embodiment, a cut is provided in each interconnection 5 as the slit 7. That is, the width of the slit 7 is substantially zero. Such the slit 7 can be formed by cutting off each interconnection 5 by using a cutter (blade). At this time, only the interconnections 5 or both of the interconnections 5 and the tape base 2 may be cut off. By providing the cut as each slit 7, the width “a” of each interconnection element 51 can be increased as much as possible. This can suppress progress of separation of the interconnections 5, similarly to the third embodiment.

In an example shown in FIG. 6, one slit 7 is provided per one interconnection 5. If the number of slits 7 is one, the width “a” of each interconnection element 51 is often larger than the space “b”. In such a case, the width “a” of each interconnection element 51 can be set smaller than the space “b” by increasing the number of slits 7.

The first to fourth embodiments of the present invention have been described. It is to be noted, however, these embodiments are not independent of one another but the embodiments can be combined appropriately without departure from a scope of the invention.

Also, although the present invention has been described above in connection with several embodiments thereof, it would be apparent to those skilled in the art that those embodiments are provided solely for illustrating the present invention, and should not be relied upon to construe the appended claims in a limiting sense.

What is claimed is:

1. A tape carrier package comprising:
a tape base; and
interconnections formed on said tape base and extending to intersect a cutting line,
wherein at least a slit is formed along each of said interconnections, to intersect the cutting line and to divide said interconnection into a plurality of interconnection elements.

2. The tape carrier package according to claim 1, further comprising:
a semiconductor chip mounted on said tape base; and
a test area in which test terminals are provided on said tape base to test electric characteristics of said semiconductor chip,
wherein said interconnections extend to connect said semiconductor chip and said test terminals, and
wherein said cutting line is set to separate said test area and an area in which said semiconductor chip is disposed.

3. The tape carrier package according to claim 1, wherein said slit is formed for each of said interconnections such that a width of each of said plurality of interconnection elements is narrower than a space between adjacent two of said interconnections.

4. The tape carrier package according to claim 1, wherein a plurality of said slits are provided for an intersection portion of each of said interconnections and said cutting line.

5. The tape carrier package according to claim 1, wherein said slit is a rectangular opening.

6. The tape carrier package according to claim 1, wherein the width of said slit is zero.

7. The tape carrier package according to claim 1, wherein said slit is formed such that the width of each of said plurality of interconnection elements varies gradually in an intersecting direction with said cutting line.

8. An individual tape carrier package product comprising:
a tape base;
a semiconductor chip mounted on said tape base; and
interconnections formed on said tape base and extending to intersect a cutting line,
wherein each of said interconnections is divided into a plurality of interconnection elements at an end of said tape base.

9. A manufacturing method of a tape carrier package, comprising:
providing a tape base;
forming interconnections on said tape base to intersect a cutting line; and
forming at least a slit in each of said interconnections,
wherein said forming at least a slit comprises:
forming at least a slit along each of said interconnections, to intersect the cutting line and to divide said interconnection into a plurality of interconnection elements.

10. A manufacturing method of an individual tape carrier package product, comprising:
providing a tape base;
forming interconnections on said tape base to intersect a cutting line;
forming at least a slit in each of said interconnections; and
cutting said tape base in which said interconnections have been formed and said slit has been formed, along said cutting line,
wherein said forming at least a slit comprises:
forming at least a slit along each of said interconnections, to intersect the cutting line and to divide said interconnection into a plurality of interconnection elements.
